(19) United States
(12) Patent Application Publication
(10) Pub. No.: US 2004/0232526 A1
(43) Pub. Date: Nov. 25, 2004

(54) Lead frame for stacked semiconductor packages, stacked semiconductor packages using it, and fabrication method thereof

(76) Inventors: Rak-Hyun Ryoo, Sungnam (KR); Jung-Hoon Kwon, Sungnam (KR)

Correspondence Address: MCDERMOTT WILL & EMERY LLP, 600 13TH STREET, N.W., WASHINGTON, DC, 20005-3096, US

(21) Appl. No.: 10/415,436

(22) PCT Filed: Dec. 26, 2002
(86) PCT No.: PCT/KR02/02439

(30) Foreign Application Priority Data
Jul. 11, 2002 (KR) 10-2002-0040483

(51) Int. Cl. H01L 23/495

(52) U.S. Cl. 257/666

(57) ABSTRACT

A lead frame for stacked semiconductor package is provided, which comprises a plurality of lead pins having same length, thickness, pitch and arranged to correspond to exterior leads of a semiconductor package, and a frame holding the lead pins, wherein at least one lead pin is integrally formed with an adjacent lead pin to be electrically connected and a part of the end of the lead pin is cut to be shorter that other lead pins. Additionally and/or alternatively, at least one lead pin is electrically connected with a remote lead pin through an additional lead or a lead line.

### TECHNICAL FIELD

The present invention relates to a lead frame for stacked semiconductor packages, stacked semiconductor packages using it, and its fabrication method.

### BACKGROUND ART

Most electronic devices include circuits using a semiconductor package with various integrated circuits inserted therein, and the semiconductor package is mounted as a single package form on a printed circuit board (PCB). As the electronic devices become compact and portable products are favored, parts of the electronic devices get light, thin, short and small, and reduction of a mounting area of the unit parts in line with the reduced mounting space is focused on. For this purpose, a package technique for improving a mounting efficiency of the semiconductor package is being rapidly developed.

Recently, a stacked package technique that a plurality of semiconductor packages are stacked and made to modules to better the mounting efficiency has entered a stage of practical use.

A conventional representative stacking technique will now be described.

FIGS. 1A and 1B are perspective view and sectional view of a stacked package of a conventional semiconductor package.

As illustrated, in the conventional art, after stacking positions are adjusted, two semiconductor packages 12a and 12b are positioned at an upper side and at a lower side, of which a plurality of leads 14a and 14b are connected by using conductor lines called header (16a˜16g), thereby performing a stacking.

Or, according to circumstances, like the header 16e, a lead connection portion of the two semiconductor packages is cut and the header traverses the upper portion of the stacked semiconductor package 12b, for connection.

However, such a conventional stacked package has the following problems.

That is, it inconveniently uses the plurality of headers, auxiliary conductor lines. In addition, it is disadvantageous in terms of process that cutoff of a portion as required or connection of headers to the plurality of corresponding leads cause problems as a pitch (interval between leads) of the lead of the semiconductor package becomes narrow.

FIGS. 2A and 2B show another conventional art.

As illustrated, a lower semiconductor package 20 bonded to the PCT (not shown), an upper semiconductor package 20b to be stacked is positioned on the lower semiconductor package, and leads 01P, 02P, 23P, . . . , 19P (not connected) are connected, forming a layer structure.

The semiconductor packages 20a and 20b used for the stacked package are fabricated to have the same functional leads. And in this respect, a PCB 22, one of auxiliary connection unit that is able to change interconnection of the leads, is inserted between the lower semiconductor package and the upper semiconductor package in order to change a function of a specific lead (36P of 20B) of the semiconductor package to have a normal function after a stacked package of the semiconductor packages is completed.

The upper and lower semiconductor packages with the PCT inserted therebetween are stacked by soldering so as to be electrically connected between the leads. Reference numeral 24 denotes a connection portion between leads. As shown in FIG. 2B, in the stacked package, since the 19^{th} lead 19Pb of the upper semiconductor package 20b is connected to the 26^{th} lead 26Pb through a plurality of connection portions 24, a function of the specific lead 26P of the stacked package is changed.

Leads of the semiconductor package has such an initial fabrication form (‘zigzag’ form) as the leads of the lower semiconductor package 20a of FIG. 2A. Thus, in order to facilitate stacking, such form of lead should be transformed into a ‘reverse-L’ form like the upper semiconductor package 20b, of which a portion is cut short as necessary (19Pb of 20b) and electrically open with a corresponding lead 10Pa of 20a of the lower semiconductor package.

The stacked package, however, has problems that insertion of the PCB between the two semiconductor packages leads to increase in volume of the package, and it is inconvenient to transform the form of a lead to change its function and cut the lead, which results in deterioration of a productivity.

### TECHNICAL GIST OF THE PESENT INVENTION

Therefore, an object of the present invention is to provide a novel stacking type semiconductor package which does not require an auxiliary conductor line for connection of leads or a PCB for stacking a semiconductor package.

Another object of the present invention is to provide a method for fabricating a semiconductor package with a simple stacking process and low production cost.

### DETAILED DESCRIPTION OF THE INVENTION

In order to achieve the above objects, there is provided a lead frame for stacking a semiconductor package including: a plurality of lead pins arranged corresponding to outer leads of a semiconductor package and having the same length, thickness and pitch; and a frame for supporting the lead pins, wherein at least one of the lead pins is integrally formed with an adjacent lead pin so as to be electrically connected thereto and a portion of an end of the integrally formed lead pin is cut to be shorter than other lead pins.

To achieve the above objects, there is provided a lead frame for stacking a semiconductor package including: a plurality of lead pins arranged corresponding to outer leads of a semiconductor package and having the same length, thickness and pitch; and a frame for supporting the lead pins, wherein at least one of the lead pins is connected to a lead pin which is not adjacent by an auxiliary lead or a lead line so as to be electrically connected thereto.

### BRIEF DESCRIPTION OF THE DRAWINGS

FIG. 1A is a perspective view of a stacked package of a semiconductor chip in accordance with one conventional art;

FIG. 1B is a sectional view of the stacked package of FIG. 1A;

FIG. 2A is a perspective view of a stacked package of a semiconductor chip in accordance with another conventional art;

FIG. 2B is a sectional view of the stacked package of FIG. 2A;

FIG. 3A is a plan view of a general semiconductor package;

FIG. 3B is a sectional view of the semiconductor package of FIG. 3A;

FIG. 3C is a side view of the semiconductor package of FIG. 3A;

FIG. 4A is a plan view of a lead frame in accordance with a first embodiment of the present invention;

FIG. 4B is an enlarged view of a portion ‘A’ of FIG. 4A;

FIG. 5A is a sectional view showing how an upper package is in contact with a lead pin;

FIG. 5B is a sectional view showing how a lower package is in contact with a lead pin;

FIG. 5C is a sectional view showing how the upper and lower packages are in contact with the lead pin;

FIG. 5D is a sectional view showing that the upper package is in contact with the lead pin while the lower package is not in contact with the lead pin;

FIG. 6A is a plan view of a lead frame in accordance with a second embodiment of the present invention;

FIG. 6B is an enlarged view of a portion ‘B’ of FIG. 6A;

FIG. 6C is a view showing a section of a lead pin and an auxiliary lead;

FIG. 6D is a sectional view of a trim line;

FIG. 6E is a plan view of a frame after the lead pin is cut out

FIG. 7A is a plan view of a lead frame in accordance with a third embodiment of the present invention;

FIG. 7B is a plane view showing a portion ‘C’ of FIG. 7A; and

FIG. 8 is a flow chart of a sequential process of stacking a semiconductor package in accordance with the present invention.

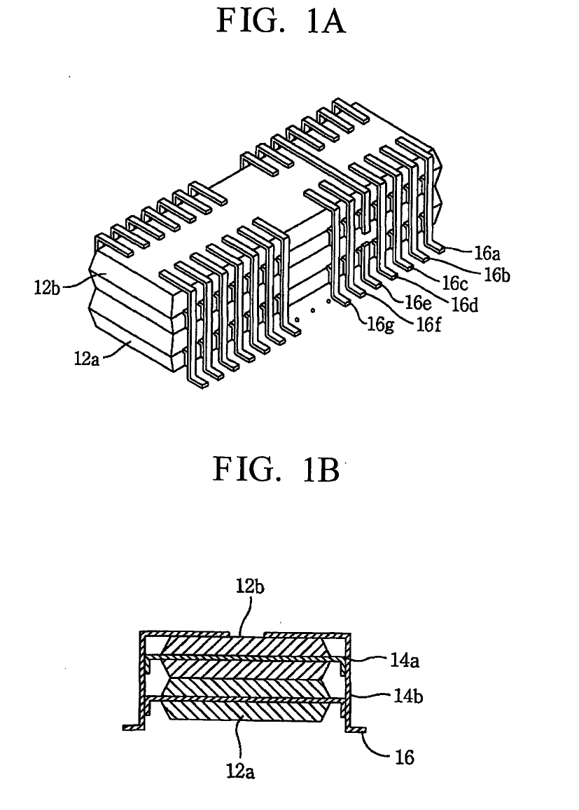

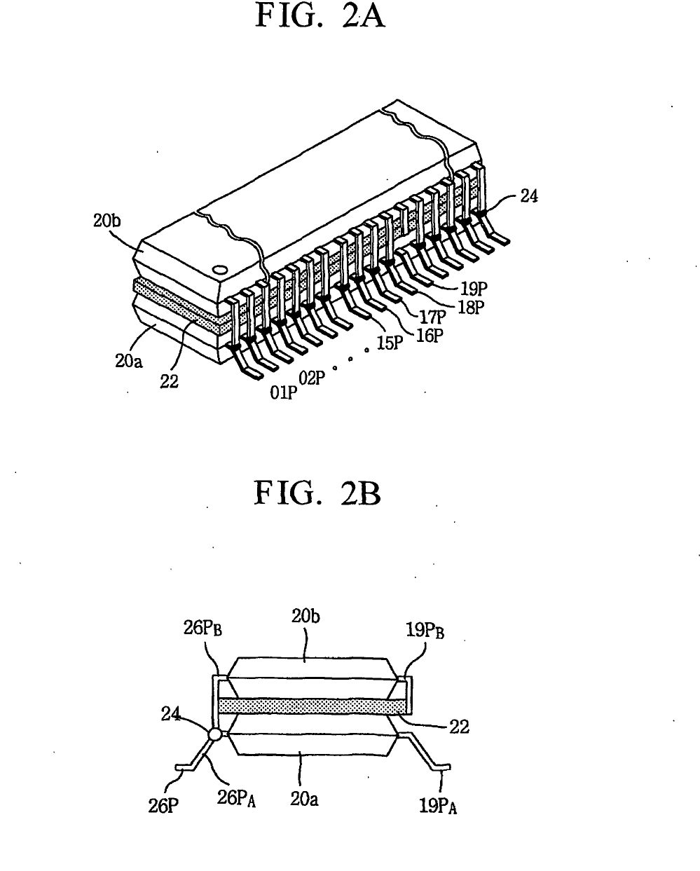

### MODE FOR CARRYING OUT THE PREFERRED EMBODIMENTS

The present invention will now be described with reference to accompanying drawings.

As for the existing stacked semiconductor packages, since an upper package and a lower package are manually stacked, its mass production is difficult, since an additional lead or an interlayer is inserted in staking packages, a stacking structure is complicated and has a large volume.

Comparatively, a lead frame of the present invention has advantages that a mass production is possible by automating stacking of packages and a mounting space in mounting various electronic equipments can be reduced by minimizing the volume of the stacked package.

Especially, since a plurality of lead frames can be formed in a matrix form on one metal plate, a productivity can be highly enhanced. In addition, the semiconductor package can be stacked by more than two layers, of which any outer leads can be mutually electrically connected and disconnected, so that its application coverage is notably wide.

The present invention will now be described in detail with reference to the accompanying drawings.

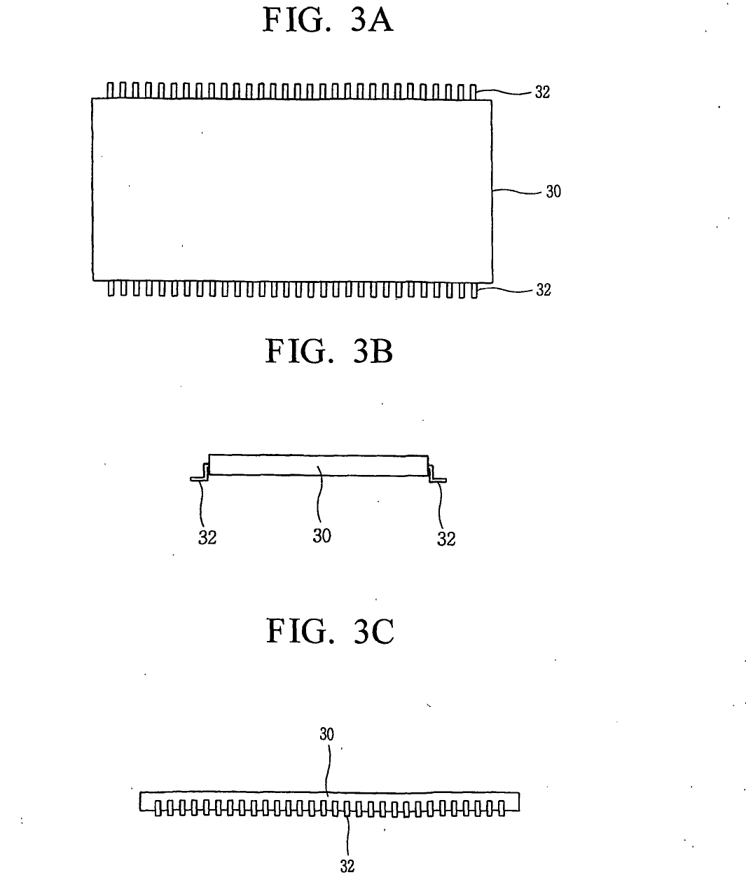

FIGS. 3A to 3C show the structure of a general semiconductor package.

FIG. 3A is a plan view of the semiconductor package with a plurality of outer leads 32 extended outwardly from the package body 30, and FIGS. 3B and 3C show its section and side.

The lead frame of the present invention is basically formed having the same arrangement and interval as the outer leads so as to correspond to the outer leads of the semiconductor package. Intervals of lead pins of the lead frame are preferably the same as the outer leads, and a thickness of the lead pin is the same as or smaller than the outer lead of the package because the thinner the lead pin, the more the stacked volume is reduced in the package stacking.

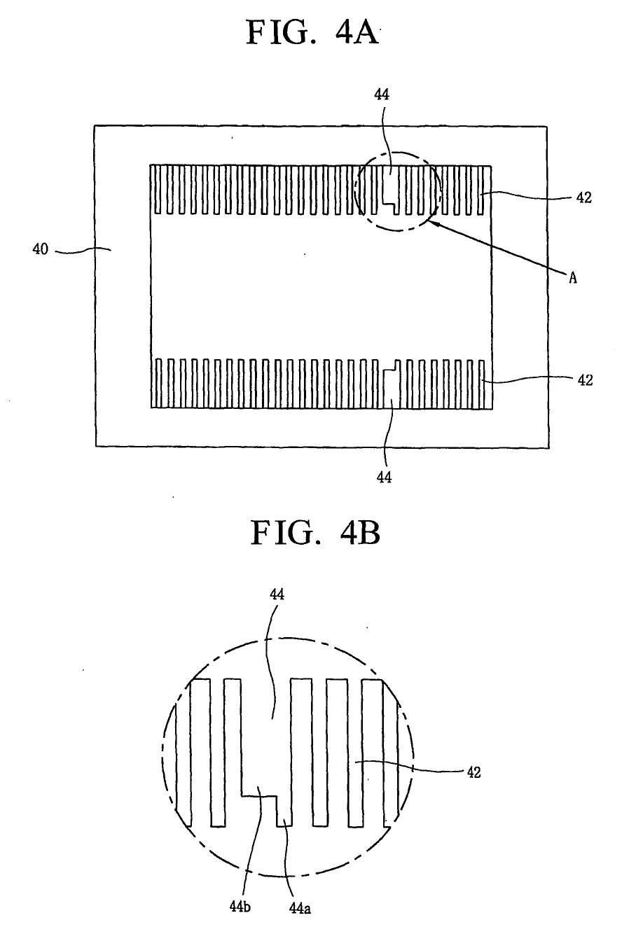

FIG. 4A shows a lead frame in accordance with a first embodiment of the present invention.

As shown, lead pins 42 formed with the same arrangement as the outer leads of the semiconductor package are extended from the frame 40. In particular, while most of the lead pins have the same length and intervals, some two lead pins are integrally formed, like a reference numeral 44, of which a portion of an end is cut out.

FIG. 4B is an enlarged view of a portion ‘A’ of FIG. 4A. It is noted that the end of the part 44 formed as two lead pins are connected is divided into a portion 44a with the same length as other lead pins and a shorter portion 44b roughly with a ‘reversed L’ or ‘L’ shape.

When two semiconductor packages are stacked up and down and the outer leads of the upper package and the outer leads of the lower package are mutually electrically connected, the lead pin 44, which is formed as two lead pins are integrally connected, serves to allow adjacent two outer leads of one layer to be electrically connected and corresponding outer leads of the upper layer and to allow the lower layer to be electrically disconnected.

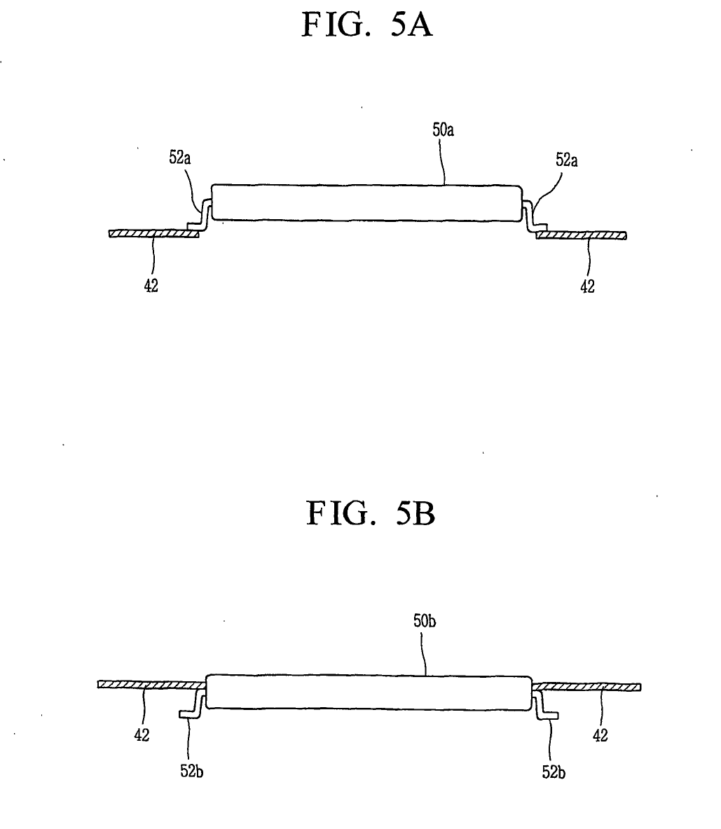

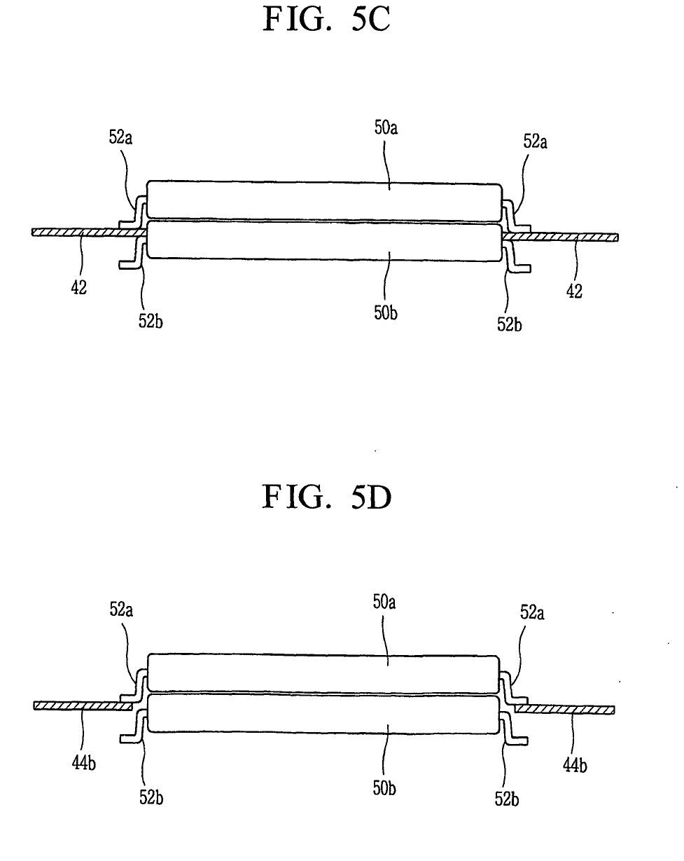

FIG. 5A shows how the lead pin 42 of the lead frame of the present invention is in contact with the outer lead 52a of the upper package 50a of the two semiconductor packages to be stacked. FIG. 5B shows how the lead pin 42 is in contact with the outer lead 52b of the lower package 50b.

In comparison of FIGS. 5A and 5B, it is noted that an outer lead of the package is bent from the end of the package downwardly and then bent again. Thus, a contact face when the lead pin is in contact with the outer lead of the upper package and a contact face when the lead pin is in contact with the outer lead of the lower package are somewhat different. That is, when the lead pin is in contact with the outer lead of the upper package, comparatively, it can come in much contact with the outer lead, whereas when the lead pin is in contact with the outer lead of the lower package, only the most end portion of the lead pin comes in contact with the outer lead.

FIG. 5C shows how the upper package and the lower package are in contact with the lead pins simultaneously. The two semiconductor packages are stacked up and down and the upper leads and the lower leads are electrically connected by the lead pins so as to be operated as one semiconductor device. Accordingly, in case of a memory device, it can attain an effect that its capacity is increased.

The lead pin and the outer lead can be contacted by soldering or other method, which, especially, can be automated through a surface mounting technology (SMT).

FIG. 5D shows a stacked section of the portion of the lead frame where two adjacent lead pins are mutually connected. The two adjacent outer leads of the upper package being in contact with the lead pin 44 as connected in FIG. 4B are to be electrically connected. The portion 44a of the end of the lead pin with the same length as other lead pins is where the leads of the upper package and the leads of the lower package are in contact with each other as shown in FIG. 5C.

Meanwhile, the outer lead 52a of the upper package comes in contact with the portion 44b of the end of the lead pin with the shorter length, whereas the outer lead 52b of the lower package is not in contact with the lead pin 44b and electrically disconnected.

Overall, in the two stacked packages, the corresponding outer leads of the upper and lower packages are electrically connected by each lead pin, adjacent outer leads in the upper package are electrically connected and some outer leads of the upper and lower packages are electrically disconnected. Therefore, an electrical signal can be applied to the stacked package, or the upper package and the lower package can be electrically controlled separately.

After the upper and lower packages come in contact with to corresponding lead pins of the lead frame, the lead pins are cut from the frame to separate the stacked package. A trim line can be formed with a smaller thickness that the lead pin at the central portion in a longitudinal direction of the lead pin.

The lead pin is preferably made of a metal material which is light and has a good electric conductivity and a high strength. Usually, it can be copper, and in case that a high strength is desired, a stainless steel with a gold-plated surface can be used as the lead pin.

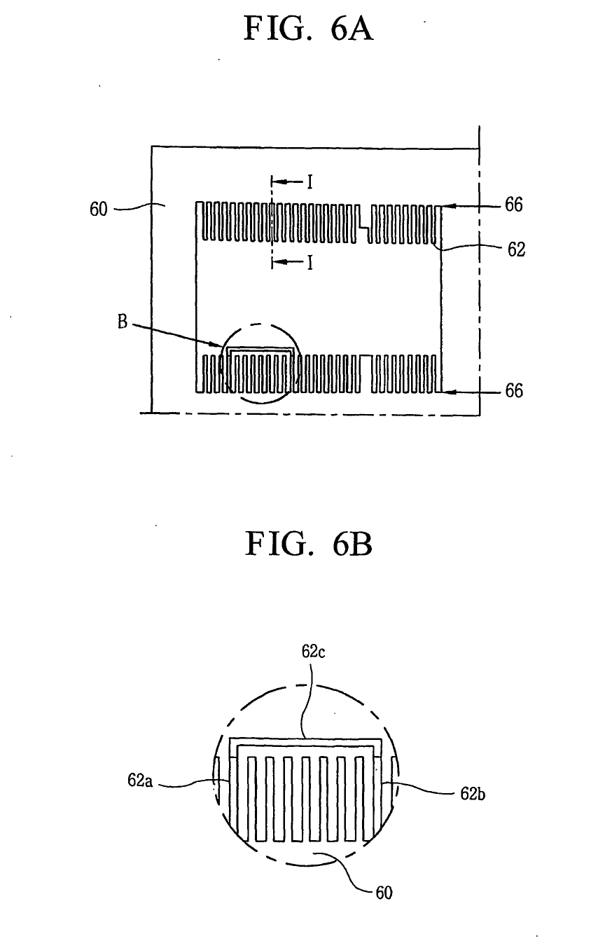

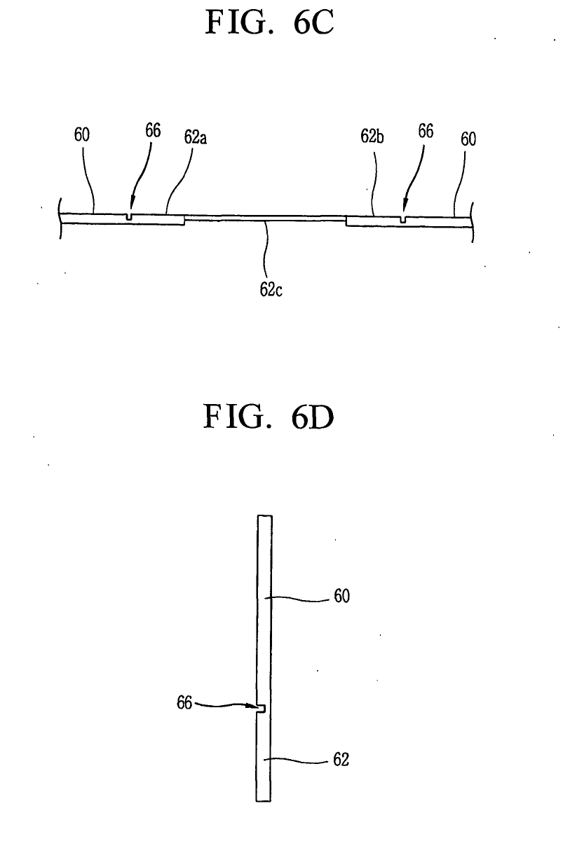

FIG. 6A shows a lead frame in accordance with a second embodiment of the present invention, in which a plurality of lead pins 62 are formed extended inside a frame 60.

Unlike in the previous embodiment, it is noted that some lead pins distanced from each other are connected by a separately extended lead line. FIG. 6B is an enlarged view of a portion ‘B’ of FIG. 6A, in which one lead pin 62a and a remotely positioned lead pin 62b are connected by an auxiliary lead 62c, a connection portion. This construction renders two distanced lead pins to be electrically connected like in the first embodiment in which the adjacent two lead pins are electrically connected. In this manner, the mutually distant outer leads of the two semiconductor packages stacked at a lower portion and at an upper portion of the lead frame can be electrically connected.

The auxiliary lead 62c connecting the two lead pins can be integrally formed with the lead pins 62a and 62b with the same material. In this respect, especially, it is preferred that the auxiliary lead 62c is thinner than the lead pin. The reason is because when the two semiconductor packages are stacked with the lead frame interposed therebetween and the outer leads are in contact with the lead pins, if the auxiliary lead placed between the two packages is thick, the stacking thickness of the package is increased.

Therefore, the thickness of the auxiliary lead is preferably in the range of 40˜70% of the thickness of the lead pins in consideration of the overall fabrication condition of the lead frame, and optimally, it is 50%.

Meanwhile, one of the lead pins 62a and 62b can have the thickness in the range of 40˜70% of the thickness of other lead pins. That is, it can have the same thickness as that of the auxiliary lead.

FIG. 6C shows a section of the two lead pins 62a and 62b and the auxiliary lead 62c connecting them.

If the thickness of the lead pin denoted by reference numeral 62b is relatively small, outer leads of the upper package being in contact with the two lead pins are electrically connected, but in this respect, since one of the outer leads of the lower package does not come in contact with the lead pin 62b with the relatively small thickness, two outer leads of the lower package. are electrically disconnected. This construction has the same function as that of the construction of the first embodiment in which the adjacent two lead pins are integrally formed and a portion of the end thereof is long while the remaining portion is short.

When the upper and lower packages are stacked at the upper and lower surfaces of the lead frame and the outer leads and the lead pins come in contact with each other, the lead pins are cut out from the frame 60.

In order to facilitate the cutting, a trim line can be formed, with a smaller thickness than that of the lead pin, where the lead pin and the frame are met.

FIG. 6D shows a section taken along line I-I of FIG. 6A. It is shown that the trim line 66 is formed where the frame 60 and the lead pin 62 extended from the frame are met. FIG. 6E shows the frame 60 after the lead pins are cut out.

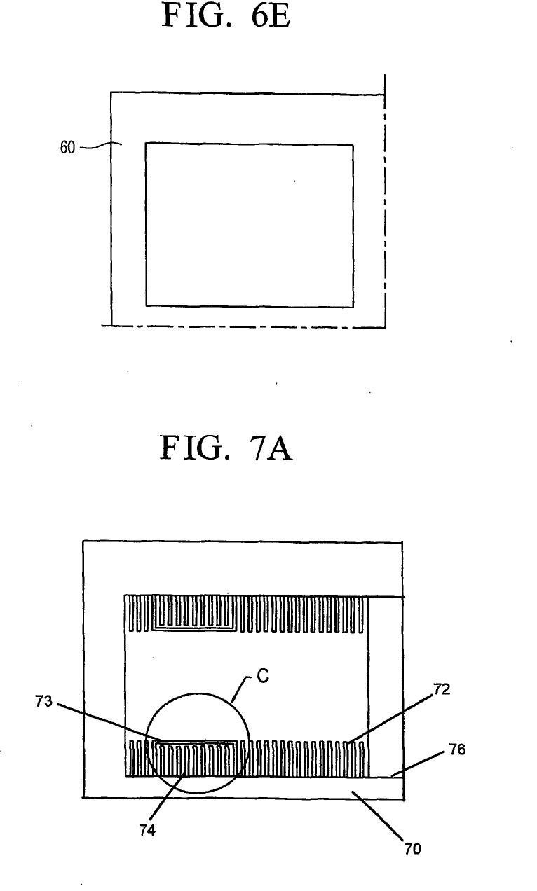

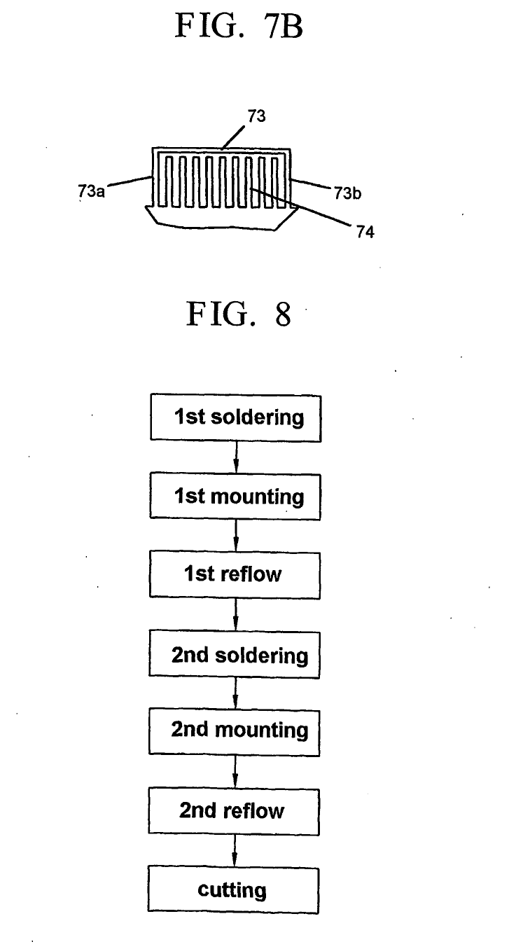

FIGS. 7A and 7B show a lead frame in accordance with the third embodiment of the present invention.

A plurality of lead pins 72 are formed extended inside the frame 70. Like in the second embodiment of the present invention, some lead pins distanced apart are connected by a lead line 73. However, the connection lead line 73 is different from that of the second embodiment in that it is not an auxiliary lead and integrally formed with at least two lead pins, has the same thickness as that of the lead pins and is formed at the same level of the end of the lead pins. In addition, lead pins 74 placed between the two lead pins connected by the lead line are shorter than other lead pins.

FIG. 7B is an enlarged view of a portion ‘C’ of FIG. 7A, in which one lead pin 73a is connected to the other lead pin 73b distanced from, the lead pin 73a by the lead line 73 which corresponds to a connection portion. Accordingly, outer leads distanced from each other of the two semiconductor packages stacked at an upper portion and at a lower portion of the lead frame can be electrically connected. The lead line 73 s integrally formed with the lead pin and has the same material, and it is preferred that the lead line 73 has the same thickness as the lead pins in terms of simplification of a production process.

When the two semiconductor packages are stacked with the lead frame interposed therebetween and the outer leads are in contact with the lead pins, the lead line is not positioned between the two packages. Thus, the package stacking thickness is not increased.

One of the lead pins 73a and 73b connected by the lead line 73 may be in the range of 40˜70% of the thickness of other lead pins. In such a case, the outer leads of one of the upper and lower packages being in contact with the two lead pins are electrically connected. But one of the outer leads of the other package is not in contact with the lead pin with a relatively small thickness, and thus, the two outer leads of the lower package are electrically disconnected.

As stated above, two or more semiconductor packages can be stacked up and down by using the lead frame.

Specifically, a stacked semiconductor package is provided with a first semiconductor package having a plurality of outer leads, a second semiconductor package having a plurality of outer leads and a plurality of auxiliary lead pins by using the lead frame, wherein the first semiconductor package and the second semiconductor package are stacked up and down, the outer leads of the first semiconductor package and the outer leads of the second semiconductor package are mutually connected by the auxiliary lead pins, at least two or more outer leads of the first semiconductor package are mutually electrically connected by the auxiliary lead pins, and at last one of the auxiliary lead pins is electrically connected to the outer lead of the first semiconductor package but not electrically connected to the outer lead of the second semiconductor package.

The outer leads of the first semiconductor package which are mutually electrically connected by the auxiliary lead pins may be adjacent to each other or may not be adjacent to each other. In addition, some of the outer leads of the upper or the lower packages may not be in contact with the lead pins. Accordingly, in the present invention, the outer leads of the semiconductor package can be connected or disconnected in various forms. Thus, the present invention can be adopted to various packages.

Another feature of the present invention is that the existing surface mounting technique and equipments can be used as it is for stacking the semiconductor package. Equipments used in the surface mounting line include a screen printer for printing a solder to a PCB or a package, a chip mount and a releasing mount for mounting various chips or packages on the PCB; and a reflow oven for hardening the solder, etc.

Accordingly, several stacked semiconductor packages can be produced at a time by mounting the semiconductor package at the upper portion and the lower portion of the lead frame by using such surface mounting equipments, and cutting the lead pins from the frame.

FIG. 8 is a flow chart of a sequential process of the fabrication.

First, a lead frame is prepared. The lead frame is generally fabricated through molding, or can be fabricated by other methods.

After the lead frame is prepared, a solder is pointed at an upper portion of the lead pin o the lead frame in the screen printer (first soldering), and the upper package is mounted on the lead frame in the releasing mount to allow the outer leads of the package to be in contact with the lead pins (first mounting).

Next, the solder is strengthened in the reflow oven (first reflowing). After the upper package finishes its mounting, a solder is pointed at the lower portion of the lead pin for mounting of the lower package (second soldering) and the lower package is mounted on the lead frame in the releasing mount to allow the outer leads of the package and the lead pins to be in contact with each other (second mounting). And then, the solder is strengthened in the reflow oven (second reflowing).

In the above process, the order of contacting the lead pins of the lead frame to outer leads of the upper semiconductor and to the outer leads of the lower semiconductor can be changed, or they can be simultaneously attached. Especially, simultaneous mounting of the upper package and the lower package at the upper and lower portion of the lead frame to allow the outer leads and the lead pins to be in contact with each other would shorten the process time.

After the upper and lower packages are completely mounted, the lead pins are cut from the frame to detach the stacked package (cutting the lead frame). All the processes are successively performed by using the surface mounting equipments, and several packages can be stacked at a time according to the number of lead frames.

### Industrial Applicability

As so far described, the present invention has the following advantages.

That is, first, since the package stacking is automated over the lead frame, a mass production is possible.

Second, the volume of the stacked package can be minimized so that when it is mounted in various electronic equipments, its mounting space can be reduced.

Third, a plurality of lead frames can be formed in a matrix form on one metal plate, so that a productivity can be remarkably improved.

Lastly, the semiconductor packages can be stacked by two or more layers and any ones of the outer leads of the stacked package can be mutually electrically connected or disconnected, and thus, its application coverage is very wide.

1. A lead frame for stacking a semiconductor package comprising:
a plurality of lead pins arranged corresponding to outer leads of a semiconductor package and having the same length, thickness and pitch; and
a frame for supporting the lead pins,
wherein at least one of the lead pins is integrally formed with an adjacent lead pin so as to be electrically connected thereto and a portion of an end of the integrally formed lead pin is cut to be shorter than other lead pins.

2. The lead frame of claim 1, wherein a trim line is formed with a smaller thickness than that of the lead pin at a central portion in a longitudinal direction of the lead pins.

3. The lead frame of claim 1, wherein a trim line is formed with a smaller thickness than that of the lead pin at a portion where the lead pin and the frame meet.

4. The lead frame of claim 1, wherein the lead pin is made of copper.

5. The lead frame of claim 1, wherein the lead pin is made of a stainless steel with a gold-plated surface.

6. A lead frame for stacking a semiconductor package comprising:
a plurality of lead pins arranged corresponding to outer leads of a semiconductor package and having the same length, thickness and pitch; and
a frame for supporting the lead pins,
wherein at least one of the lead pins is connected to a lead pin which is not adjacent by an auxiliary lead so as to be electrically connected thereto, and one of the connected two lead pins and the auxiliary lead have a smaller thickness than that of other lead pins.

7. The lead frame of claim 6, wherein a trim line is formed with a smaller thickness than that of the lead pin at a central portion in a longitudinal direction of the lead pins.

8. The lead frame of claim 6, wherein a trim line is formed with a smaller thickness than that of the lead pin at a portion where the lead pin and the frame meet.

9. The lead frame of claim 6, wherein the lead pin is made of copper.

10. The lead frame of claim 6, wherein the lead pin is made of a stainless steel with a gold-plated surface.

11. The lead frame of claim 6, wherein one of the connected two lead pins and the auxiliary lead has a thickness in the range of 40˜70% of the thickness of other lead pins.

12. A lead frame for stacking a semiconductor package comprising:
a plurality of lead pins arranged corresponding to outer leads of a semiconductor package and having the same length, thickness and pitch; and
a frame for supporting the lead pins,
wherein at least one of the lead pins is integrally formed with a lead pin which is not adjacent thereto by a lead line so as to be electrically connected thereto, and the lead line is formed at the same level of the end of other lead pins.

13. The lead frame of claim 12, wherein a trim line is formed with a smaller thickness than that of the lead pin at a central portion in a longitudinal direction of the lead pins.

14. The lead frame of claim 12, wherein a trim line is formed with a smaller thickness than that of the lead pin at a portion where the lead pin and the frame meet.

15. The lead frame of claim 12, wherein the lead pin is made of copper.

16. The lead frame of claim 12, wherein the lead pin is made of a stainless steel with a gold-plated surface.

17. A stacked semiconductor package comprises:
a first semiconductor package having a plurality of outer leads;
a second semiconductor package having a plurality of outer leads; and
a plurality of lead pins by using the lead frame,
wherein the first semiconductor package and the second semiconductor package are stacked up and down, the outer leads of the first semiconductor package and the outer leads of the second semiconductor package are mutually connected by the lead pins, at least two or more outer leads of the first semiconductor package are mutually electrically connected by the lead pins, and at last one of the lead pins is electrically connected to the outer lead of the first semiconductor package but not electrically connected to the outer lead of the second semiconductor package.

18. The semiconductor package of claim 17, wherein the outer leads of the first semiconductor package which are mutually electrically connected by the lead pins are adjacent to each other.

19. The semiconductor package of claim 17, wherein the outer leas of the first semiconductor package which are mutually electrically connected by the lead pins are not adjacent to each other, and the lead pins include an auxiliary lead pin or a lead line formed extended between the stacked two semiconductor packages.

20. The semiconductor package of claim 19, wherein the auxiliary lead pin is thinner than the lead pin.

21. A method for fabricating a stacked semiconductor package comprising the steps of:
preparing a lead frame according to one of claims 1, 6 and 12;
printing a solder at an upper portion of the lead pin of the lead frame;
mounting an upper semiconductor package on the lead frame and allowing outer leads of the package and lead pins to be in contact with each other;
strengthening the solder;
printing the solder at the lower portion of the lead pin;
mounting a lower semiconductor package on the lead frame and allowing outer leads of the package and the lead pins to be in contact with each other;
strengthening the solder; and
cutting the lead pins from the lead frame.

22. The method of claim 21, wherein the solder printing is performed in a screen printer, the semiconductor package mounting is performed in a releasing mount, and the solder strengthening is performed in a reflow oven, which are performed as a consecutive process.
